(19) United States
(12) Patent Application Publication
(10) Pub. No.: US 2026/0175539 A1
(43) Pub. Date: Jun. 25, 2026

(54) LAMINATED GLASS ARTICLES AND OTHER ARTICLES INCLUDING THE SAME

(71) Applicant: CORNING INCORPORATED, CORNING, NY (US)

(72) Inventor: Michael Edward DeRosa, Painted Post, NY (US)

(21) Appl. No.: 19/129,476

(22) PCT Filed: Nov. 21, 2023
(86) PCT No.: PCT/US2023/080626

§ 371 Date: May 13, 2025

Related U.S. Application Data
(60) Provisional application No. 63/428,757, filed on Nov. 30, 2022.

(51) Int. Cl. B32B 17/10; B32B 7/12; H10H 29/85; H10K 59/80

(52) U.S. Cl. CPC B32B 17/10; B32B 7/12; H10H 29/8506; H10K 59/872; B32B 2250/03; B32B 2250/40; B32B 2255/10; B32B 2255/24; B32B 2264/1021; B32B 2264/302; B32B 2307/73; B32B 2307/7376; B32B 2333/08; B32B 2457/20

(57) ABSTRACT

According to one or more embodiments, a laminated glass article may include a first polymer layer, an impact-load-distributing layer comprising a shear-thinning fluid, a glass layer disposed on the impact-load-distributing layer, an adhesive layer disposed over the glass layer, and a second polymer layer disposed over the adhesive layer. The impact-load-distributing layer may be disposed over the first polymer layer. The laminated glass article may have a bend radius of 10 millimeters or less. In additional embodiments, a laminated glass article may comprise an impact-load-distributing layer comprising a shear-thinning fluid, and a glass layer disposed on the impact-load-distributing layer, where the laminated glass article may have a bend radius of 10 millimeters or less.

### CROSS-REFERENCE TO RELATED APPLICATIONS

This application claims the benefit of priority under 35 U.S.C. § 119 of U.S. Provisional Application No. 63/428,757 filed Nov. 30, 2022, the content of which is incorporated herein by reference in its entirety.

### TECHNICAL FIELD

Embodiments of the present disclosure generally relate to glass articles and, more specifically, to laminated glass articles.

### BACKGROUND

A cover substrate for a display of an electronic device protects a display screen and provides an optically transparent surface through which a user can view the display screen. Recent advancements in electronic devices (e.g., handheld and wearable devices) are trending towards lighter devices with improved bendability and/or flexibility and reliability. The weight of different components of these devices, including protective components, have been reduced to create lighter devices. Further, flexible cover substrates have been developed to compliment flexible and foldable display screens. However, when increasing the flexibility of a cover substrate, other characteristics of the cover substrate may be sacrificed. For example, increasing flexibility may in some situations, among other things, increase weight, reduce optical transparency, reduce scratch resistance, reduce puncture resistance, and/or reduce thermal durability.

Therefore, a continuing need exists for innovations in cover substrates for consumer products, for example cover substrates for protecting display screens, and in particular, flexible and/or bendable display screens.

### SUMMARY

According to one or more embodiments, a laminated glass article may comprise a first polymer layer, an impact-load-distributing layer comprising a shear-thinning fluid, a glass layer disposed on the impact-load-distributing layer, an adhesive layer disposed over the glass layer, and a second polymer layer disposed over the adhesive layer. The impact-load-distributing layer may be disposed over the first polymer layer. The laminated glass article may have a bend radius of 10 millimeters or less.

According to one or more additional embodiments, a laminated glass article may comprise an impact-load-distributing layer comprising a shear-thinning fluid, and a glass layer disposed on the impact-load-distributing layer. The laminated glass article may have a bend radius of 10 millimeters or less.

Additional features and advantages of the embodiments described herein are set forth in the detailed description, the claims, and the appended drawings.

The foregoing general description and the following detailed description provide various embodiments and provide an overview or framework for understanding the nature and character of the claimed subject matter. The accompanying drawing provides a further understanding of the various embodiments, and are incorporated into and constitute a part of this specification. The drawing and the description explain the principles and operations of the claimed subject matter.

### BRIEF DESCRIPTION OF THE DRAWING

The following detailed description of specific embodiments of the present disclosure can be best understood when read in conjunction with the following drawing, where like structure is indicated with like reference numerals and in which:

FIG. 1 is a schematic cut-away view of a laminated glass article, according to one or more embodiments as described herein;

FIG. 2 is a schematic cut-away view of a laminated glass article, according to one or more embodiments as described herein;

FIG. 3 is a schematic cut-away view of another laminated glass article, according to one or more embodiments as described herein;

FIG. 4A is a schematic cut-away view of a laminated glass article including a polymeric encapsulating matrix, according to one or more embodiments as described herein;

FIG. 4B is a schematic cut-away view of another laminated glass article including a polymeric encapsulating matrix, according to one or more embodiments as described herein;

FIG. 4C is schematic cut-away view of a laminated glass article including a polymeric encapsulating matrix, according to one or more embodiments as described herein;

FIG. 4D is a schematic cut-away view of a laminated glass article including a polymeric encapsulating matrix, according to one or more embodiments as described herein;

FIG. 5 is an article implementing a laminated glass article, according to one or more embodiments as described herein; and

FIG. 6 shows example data, as explained in detail herein.

Reference will now be made in greater detail to various embodiments, embodiments of which are illustrated in the accompanying drawing. Whenever possible, the same reference numerals will be used throughout the drawing to refer to the same or similar parts.

### DETAILED DESCRIPTION

According to one or more embodiments, the present disclosure is directed to laminated glass articles that may include a glass layer and an impact-load-distributing layer that includes a shear-thinning fluid. The glass layer may be disposed on the impact-load-distributing layer. As described herein, according to one or more embodiments, such a configuration may provide for enhanced mechanical protection of the glass layer.

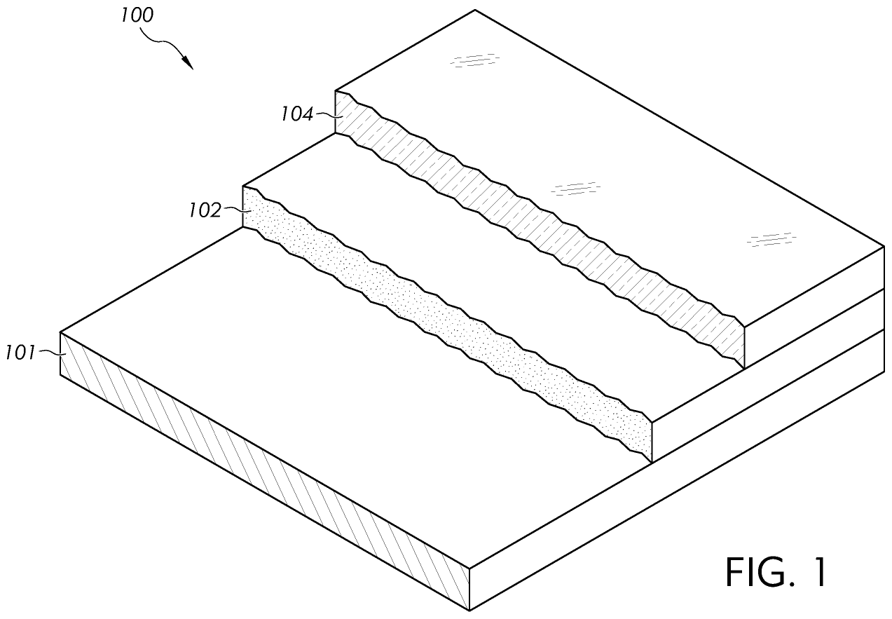

Now referring to FIG. 1, a laminated glass article 100 is depicted. The laminated glass article 100 may include an impact-load-distributing layer 102 and a glass layer 104. As illustrated in FIG. 1, and in embodiments, the glass layer 104 may be disposed on the impact-load-distributing layer 102. The laminated glass article 100 may also include a substrate 101, of which the impact-load-distributing layer 102 may be disposed on or disposed over. As depicted in FIG. 1, the substrate 101 may be any material, such as a plastic or polymeric material, but particular embodiments of substrates are described hereinafter in the context of additional embodiments. In some embodiments, the substrate 101 is a polymeric sheet, or in other embodiments the substrate 101 may be a portion of an electronic display, such as an LCD panel, LED, OLED panel, or the like.

As used herein, “disposed on” means that a first layer and/or component is in direct contact with a second layer and/or component. A first layer and/or component “disposed on” a second layer and/or component may be deposited, formed, placed, or otherwise applied directly onto the second layer and/or component. In other words, if a first layer and/or component is disposed on a second layer and/or component, there are no layers disposed between the first layer and/or component and the second layer and/or component. A first layer and/or component described as “bonded to” a second layer and/or component means that the layers and/or components are bonded to each other, either by direct contact and/or bonding between the two layers and/or components or via an adhesive layer. If a first layer and/or component is described as “disposed over” or “disposed under” a second layer and/or component, other layers may or may not be present between the first layer and/or component and the second layer and/or component.

As described herein, the glass layer 104 may include or consist of a glass material. The glass layer 104 may be flexible. As used herein, “flexible” refers to a layer or article having a bend radius, by itself, of less than or equal to 10 millimeters (mm). For example, and in embodiments, the glass layer 104 may have a bend radius of 10 mm or less, such as from 1 mm to 10, from 1 mm to 5 mm, from 5 mm to 10 mm, or any smaller range therein, such as from 3 mm to 4 mm.

It is contemplated that a variety of glass compositions may be suitable for use in the embodiments described herein. According some embodiments, the glass composition may be 68.88 mol. % SiO₂, 10.26 mol. % Al₂O 3, 5.45 mol. % MgO, 0.06 mol. % CaO, 15.18 mol. % Na₂O, 0.17 mol. % SnO₂, and 0.17 mol. % SnO₂.

The glass layer 104 may have a thickness of less than or equal to 300 microns, such as from 1 micron to 25 microns, from 25 microns to 50 microns, from 50 microns to 100 microns, from 100 micron to 200 microns, from 200 microns to 300 microns, or any combination of these ranges.

The impact-load distributing layer 102 may include a shear-thinning fluid. As used herein, a “Newtonian fluid” refers to a class of materials that exhibit a constant viscosity at changing shear rates. Also as used herein, a “non-Newtonian fluid” refers to a class of materials that exhibit a change in viscosity at changing shear rates. As used herein, a “shear-thinning fluid” refers to a class of non-Newtonian materials that exhibit a decrease in viscosity with increasing shear rate or stress. The materials utilized in the presently disclosed embodiments that are shear-thinning fluids are not necessarily limited in terms of material.

The impact-load distributing layer 102 may have a thickness of less than or equal to 1 mm, such as less than or equal to 500 microns or 100 microns, or such as from 1 micron to 20 microns, from 20 microns to 50 microns, from 50 microns to 75 microns, from 75 micron to 100 microns, from 100 microns to 500 microns, from 500 microns to 1 mm, or any combination of these ranges.

The shear-thinning fluid may have a flow behavior index. In some embodiments, the flow behavior index may be at a selected and/or observed viscosity and shear rate, but can be at any viscosity and shear rate if not specified. As used herein, the “flow behavior index” is a relative unit of measurement that indicates the degree of non-Newtonian characteristics of a fluid, and is sometimes referred to as the power law index. As commonly understood in the art, a flow behavior index of less than one indicates a fluid that is pseudoplastic, i.e. exhibits the qualities of a shear-thinning fluid. A flow behavior index equal to one indicates a fluid that exhibits the qualities of a Newtonian fluid. A flow behavior index greater than one indicates a fluid that is dilatant, i.e. exhibits the qualities of a shear-thickening fluid. As is understood by those in the art, the flow behavior index may be described by the equation η=k\dot{γ}ⁿ⁻¹ where η is the viscosity, k is the consistency index, \dot{γ} is the shear rate, and n is the flow behavior index. A more detailed description of flow behavior index can be found in “Polymer Processing” by DH Morton-Jones, Chapman and Hall, London, 1989. Determination of the flow behavior index is generally known to those skilled in the art where, to get these parameters, one directly measures viscosity as a function of shear rate in a rheometer using either parallel plate or cone and plate geometry where the material is sheared between the two plates in rotational steady shear mode. The data may then be plotted (viscosity versus shear rate) and fit with the equation above to obtain k and n. There are a variety of geometry parameters one can vary (parallel plate diameter, gap height, cone angle, cone diameter, etc.) so as long as the geometry details are specified then the results can be reproduced. The flow behavior index may be measured several times for a particular sample, and determined as the average of the produced data.

The flow behavior index may be present with a specified shear rate and viscosity. In some embodiments, the shear rate may be greater than or equal to 100 l/s and less than or equal to 1000 l/s with a viscosity less than or equal to 10,000 Pa·s, less than or equal to 3,000 Pa·s, or even less than or equal to 1000 Pa·s. In additional embodiments, the shear rate may be greater than 1000 l/s and less than or equal to 10,000 l/s with a viscosity less than or equal to 1000 Pa·s, less than or equal to 300 Pa·s, or even less than or equal to 100 Pa·s. In additional embodiments, the shear rate may be greater than 10,000 l/s and less than or equal to 100,000 l/s with a viscosity less than or equal to 300 Pa·s, less than or equal to 100 P·s, or even less than or equal to 30 Pa·s. In additional embodiments, the shear rate may be greater than 100,000 l/s and less than or equal to 1,000,000 l/s with a viscosity less than or equal to 100 Pa·s, less than or equal to 30 Pa·s, or even less than or equal to 10 Pa·s.

In one or more embodiments, the flow behavior index may be less than 1.0, less than or equal to 0.9, less than or equal to 0.8, less than or equal to 0.7, less than or equal to 0.6, or less than or equal to 0.5 at any shear rate and any viscosity. In some embodiments, the shear-thinning fluid may have a flow behavior index of from 0 to 0.1, from 0.1 to 0.2, from 0.2 to 0.3, from 0.3 to 0.4, from 0.4 to 0.5, from 0.5 to 0.6, from 0.6 to 0.7, from 0.7 to 0.8, from 0.8 to 0.9, from 0.9 to 1, or any combination of two or more of these ranges, at any shear rate and any viscosity. According to additional embodiments, the shear-thinning fluid may have a flow behavior index of from 0.9 to 0.1, from 0.8 to 0.1, from 0.7 to 0.2, from 0.6 to 0.2, or from 0.3 to 0.5, at any shear rate and any viscosity. According to additional embodiments, any of these ranges may be present at any of the viscosity and shear rate conditions specified hereinabove.

Without being limited by theory, and as later described, shear-thinning fluids with a flow behavior index of less than 0.4 may lead to a sudden change in behavior of the impact-load-distributing layer 102. For example, for flow behavior indexes of less than 0.4, the shear-thinning fluid may thin to too high a degree upon experiencing the shear from the impacting force. Accordingly, shear-thinning fluids with a flow behavior index of less than 0.4 may not lead to a sufficient lowered resultant force, which may result in the peak bending moment of the glass layer 104 exceeding the bend radius of the glass layer 104 or contacting the substrate 101 of the laminated glass article 100, thereby damaging the glass layer 104.

According to one or more embodiments, the peak bending moment of the glass layer may be from 0.4 to 0.7, such as from 0.4 to 0.5, from 0.5 to 0.6, from 0.6 to 0.7, or any combination of these ranges. As is known in the art, the bending moment refers to the measure of the effect of bending due to the applied transverse force to a structural element, and the peak bending moment may be measured by conventional means.

According to some embodiments, the shear-thinning fluid may include hydrophobic modified colloidal particles suspended in a solution, or combinations thereof. The hydrophobic colloidal particles may include hydrophobically modified: silica particles, poly(methylmethacrylate) (PMMA) particles, polystyrene (PS) particles, or combinations thereof. The silica particles may include fumed silica. The fumed silica may be made hydrophobic by hydrophobic silane surface modification. The solution may include water, ethylene glycol (EG), polyethylene glycol (PEG), or combinations thereof. Accordingly, the shear-thinning fluid may include a suspension of polyethylene glycol and hydrophobic fumed silica.

In embodiments, the shear-thinning fluid may include less than or equal to 20 wt. % hydrophobic fumed silica, measured by weight of the shear-thinning fluid, such as from 1 wt. % to 2 wt. %, from 2 wt. % to 3 wt. %, from 3 wt. % to 4 wt. %, from 4 wt. % to 5 wt. %, from 5 wt. % to 6 wt. %, from 6 wt. % to 7 wt. %, from 7 wt. % to 8 wt. %, from 8 wt. % to 9 wt. %, from 9 wt. % to 10 wt. %, from 10 wt. % to 15 wt. %, from 15 wt. % to 20 wt. %, or any combination of these ranges, of hydrophobic fumed silica measured by weight of the shear-thinning fluid. For example, the shear-thinning fluid may include 1 wt. % to 20 wt. % hydrophobic fumed silica, or from 1 wt. % to 6 wt. % hydrophobic fumed silica, measured by weight of the shear-thinning fluid.

In one or more embodiments, all or some of the the fumed silica, the hydrophobic fumed silica, or both, may have an average particle size of less than 2 micron, or less than 800 nm, or less than 200 nm, such as from 10 nm to 10 micron, from 10 nm to less than 5 microns, less than 4 microns, less than 3 microns, less than 2 microns, or less than 200 nanometers, such as from 10 nanometer to 50 nanometers, from 50 nanometers to 100 nanometers, from 100 nanometers to 200 nanometers, from 200 nanometers to 500 nanometers, from 500 nanometers to 1 micron, from 1 micron to 2 micron, from 2 micron to 3 micron, from 3 micron to 4 micron, from 4 micron to 5 micron, from 5 micron to 10 micron, or any combination of these ranges, such as from 1 nanometer to 200 nanometer, or from 300 nanometer to 1 micron. While a broad range of particle sizes is contemplated, without being bound by theory, it is believed that particles sizes of greater than 8 microns may inhibit transparency of the material. Average particle size may be the average of all particles in a size distribution of particles in a substance.

Without being bound by theory, and as described in embodiments herein, as an impacting load contacts a surface, such as the glass layer 104, a deformation of the surface occurs as the impact is distributed across the face of the surface, causing an initial bending moment and flexing of the surface. If the initial bending moment exceeds a possible bending radius of the surface, the lower side of the surface is put under tension, leading to crack propagation and otherwise damaging to the surface. In the case of a fluid layer, such as the first impact-load-distributing layer 102, contained underneath and contacting the surface, the deformation of the surface generates a shear of the fluid layer and corresponding fluid flow due to incompressibility of the fluid. This drives a pressure drop away from the impact force and a resultant pressure that pushes back on the surface with a resultant force, contributing to an additional bending moment and flexing of the surface, thereby creating an inter-connected feedback web. Therefore, a minimization of the maximum bending moment of the surface during the impact event may be desired to reduce the chance of damage to the surface.

Accordingly, without being limited by theory, it has been found herein that as the viscosity of the fluid increases, the impact force is more rapidly absorbed, leading to a smaller initial bending moment. However, this also leads to an increased resultant force on the surface and hence higher additional bending moment. Conversely at lower viscosities, the impact force is more slowly absorbed, leading to a large initial bending moment that may exceed the possible bending radius of the surface. However, this also results in lesser resultant force on the surface, and hence a lower additional bending moment.

Consequently, it has additionally been found that the addition of a shear-thinning fluid for the fluid layer, as described in embodiments herein, may operate to initially act as a higher viscosity fluid upon initially experiencing the impact force, providing the initial rapid absorbing of the impact force and minimization of the initial bending moment. Further, after experiencing shear of the fluid due to the impact force, the shear-thinning fluid may thin and subsequently act as a lower viscosity fluid, providing a weaker force divergence and a lower resultant force, leading to minimization of the additional bending moment. The end result may be an impact-load-distributing layer 102 that minimizes the total bending moment of an overlying glass layer 104 during impact events, thereby increasing the resistance of the glass layer 104 and the resulting laminated glass article 100.

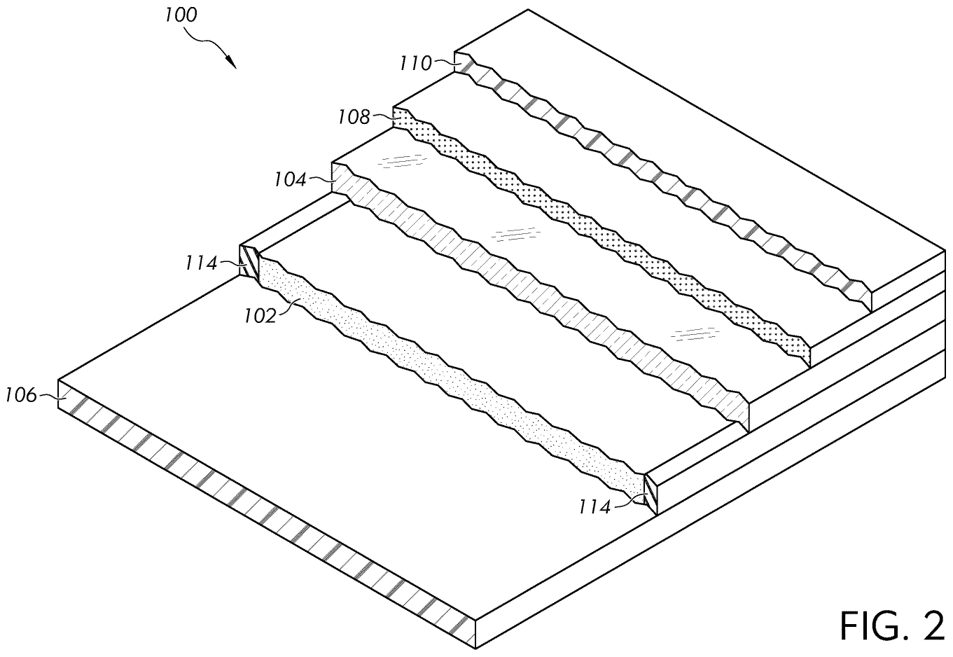

Now referring to FIG. 2, another laminated glass article 100 is illustrated. The laminated glass article 100 of FIG. 2 may be similar or identical in some respects to that of FIG. 1. For example, where like reference numbers are utilized in FIG. 2 as FIG. 1, those descriptions associated with FIG. 1 are contemplated as relevant to FIG. 2. Likewise, this applies to the other figures included here in, as well.

Referring to FIG. 2, in addition to the impact-load-distributing layer 102 and the glass layer 104, the laminated glass article 100 of FIG. 2 may further include a first polymer layer 106 (replacing the generic substrate 101 of FIG. 1), an adhesive layer 108, a second polymer layer 110, or combinations thereof. As illustrated in FIG. 2, the impact-load distributing layer 102 may be disposed over or disposed on the first polymer layer 106. The glass layer 104 may be disposed on the impact-load distributing layer 102. The adhesive layer 108 may be disposed over or disposed on the glass layer 104. The second polymer layer 110 may be disposed over or disposed on the adhesive layer 108. As is depicted, a gasket 114 may also be included, as is discussed hereinbelow.

As previously stated herein, the laminated glass article 100 may include a first polymer layer 106 and/or a second polymer layer 110. The first polymer layer 106 and/or the second polymer layer 110 may have a thickness of less than or equal to 100 microns, such as from 1 micron to 20 microns, from 20 microns to 50 microns, from 50 microns to 75 microns, from 75 micron to 100 microns, or any combination of ranges or small range therein, such as from 1 micron to 100 microns, or from 25 microns to 65 microns. In embodiments, the first polymer layer 106 and/or the second polymer layer 110 may include a polymeric material, including but not limited to, polyethylene terephthalates (PET), polyimides, polycarbonates (PC), polyethylenes (e.g., HDPE, MDPE), polypropylenes, polystyrenes, polyamides, polyamide-imides, polymethylethacrylate, other polymer blends, or combinations thereof.

Also as previously stated, the laminated glass article 100 may include an adhesive layer 108. The adhesive layer 108 may have a thickness of less than or equal to 100 microns, such as from 1 micron to 20 microns, from 20 microns to 50 microns, from 50 microns to 75 microns, from 75 micron to 100 microns, or any combination of ranges or small range therein, such as from 1 micron to 100 microns, or from 25 microns to 65 microns. The adhesive layer 108 may include a polymer curable by ultraviolet light, including, but not limited to, polyacrylic polymers, silicone polymers, or combinations thereof. Any colorless or substantially colorless adhesive may be suitable.

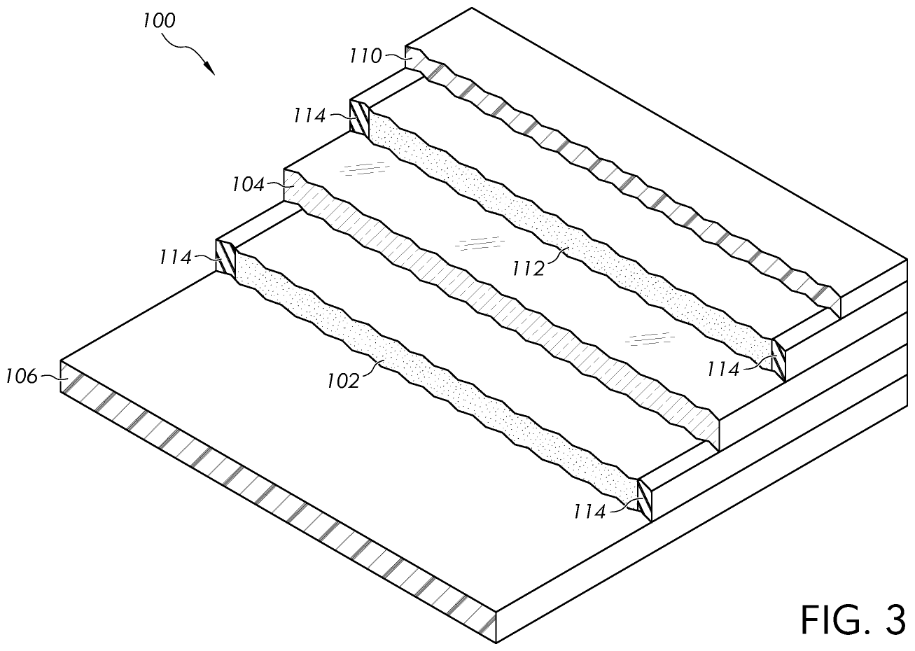

Now referring to FIG. 3, another embodiment of a laminated glass article 100 is illustrated. The laminated glass article 100 of FIG. 3 may be similar or identical in some respects to that of FIG. 1 or FIG. 2. In addition to the layers of FIG. 1 or 2, the laminated glass article 100 may further include a second impact-load-distributing layer 112. As illustrated in FIG. 3, the second impact-load-distributing layer 112 may be disposed over or disposed on the glass layer 104. Also as illustrated in FIG. 3, the second polymer layer 110 and/or the adhesive layer 108 (not shown) may be disposed over or disposed on the second impact-load distributing layer 112.

The second impact-load-distributing layer 112 may include a shear-thickening fluid. As used herein, a “shear-thickening fluid” refers to a class of materials that exhibit an increase in viscosity with increasing shear rate or stress. The second impact-load-distributing layer 112 may have a thickness of less than or equal to 100 microns, such as from 1 micron to 20 microns, from 20 microns to 50 microns, from 50 microns to 75 microns, from 75 micron to 100 microns, or any combination of ranges or small range therein, such as from 1 micron to 100 microns, or from 25 microns to 65 microns.

The shear-thickening fluid may include hydrophilic colloidal particles suspended in a solution. The hydrophilic colloidal particles may include silica particles, poly(methylmethacrylate) (PMMA) particles, polystyrene (PS) particles, or combinations thereof. The silica particles may include fumed silica. The solution may include water, ethylene glycol (EG), polyethylene glycol (PEG), or combinations thereof. Accordingly, the shear-thinning fluid may include a suspension of polyethylene glycol and hydrophilic fumed silica.

The fumed silica may be made hydrophobic by hydrophobic silane surface modification. In embodiments, the shear-thickening fluid may include less than or equal to 20 wt. % fumed silica, measured by weight of the shear-thickening fluid, such as from 1 wt. % to 5 wt. %, from 5 wt. % to 10 wt. %, from 10 wt. % to 15 wt. %, from 15.0 wt. % to 20 wt. %, or any combination of ranges or smaller range therein, such as from 1 wt. % to 10 wt. % or from 17.5 wt. % to 20 wt. % fumed silica measured by weight of the shear-thickening fluid.

Now referring to FIGS. 1-4D, and as previously stated, the laminated glass article 100 may include the impact-load-distributing layer 102 and the second impact-load-distributing layer 112, which may include a shear-thinning fluid and a shear-thickening fluid, respectively. In embodiments, the impact-load-distributing layer 102 and/or the second impact-load-distributing layer 112 may further include an encapsulating material 114 or 116. The encapsulating material may include a gasket 114, a polymeric encapsulating matrix 116, or both. The encapsulating material 114, 116 may be in direct contact with and interposed between the first polymer layer 106 and the glass layer 104, such that the shear-thinning fluid may be surrounded by the encapsulating material 114, 116 and trapped between the first polymer layer 106 and the glass layer 104. The encapsulating material 114, 116 may also be in direct contact with and interposed between the second impact-load-distributing layer 112 and the glass layer 104, such that the shear-thickening fluid may be surrounded by the encapsulating material 114, 116 and trapped between the glass layer 104 and an overlying layer, such as the adhesive layer 108.

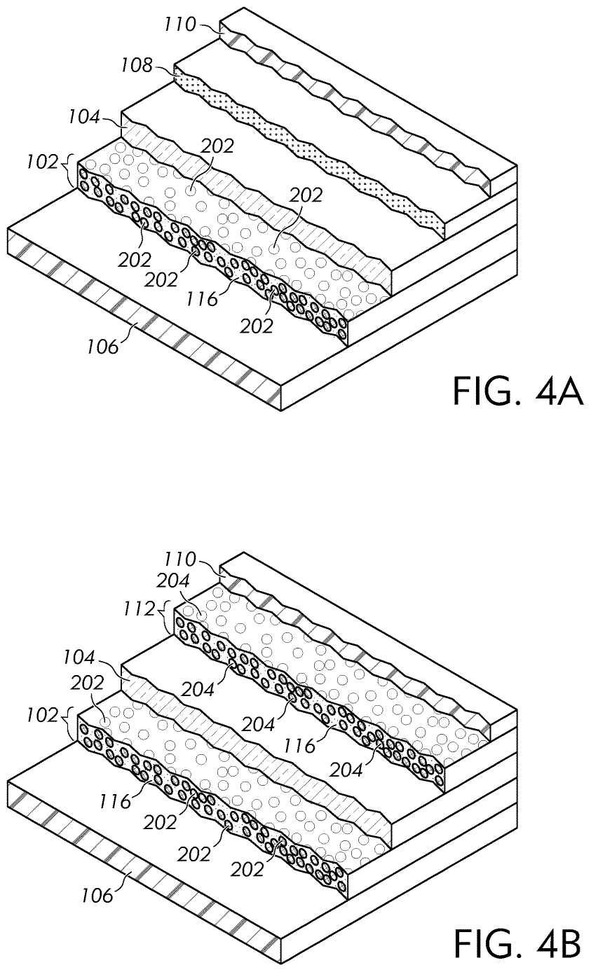

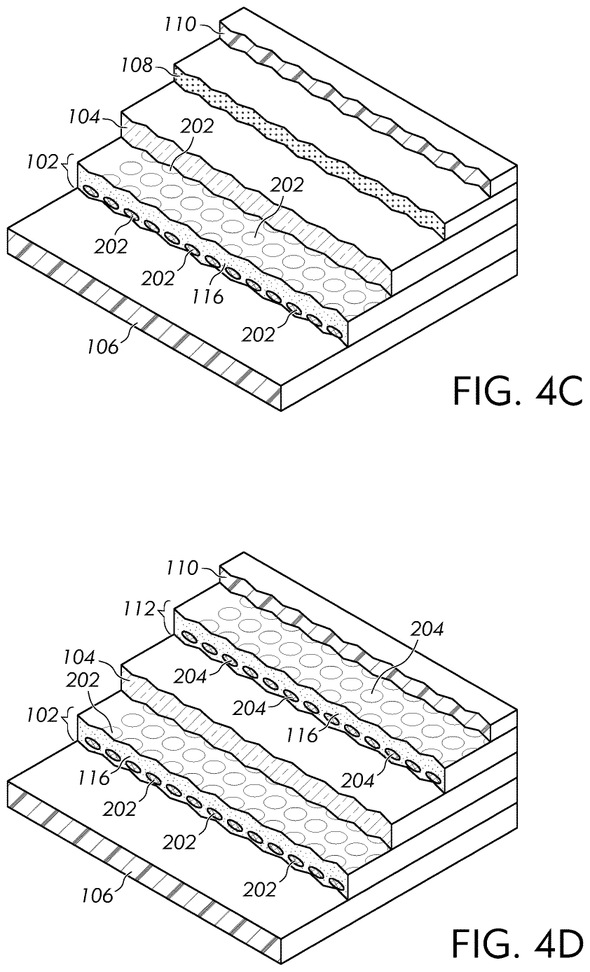

For example, and as illustrated in FIGS. 4A-4D, the shear-thinning fluid 202 or shear-thickening fluid 204 may be dispersed continuously (FIGS. 4A and 4B) or discontinuously (FIGS. 4C and 4D) within the polymeric encapsulating matrix 116. In this manner, and without being limited by theory, a polymeric component of the polymeric encapsulating matrix 116 may provide an encapsulating functionality, while the dispersed shear-thinning fluid 202 or the shear-thickening fluid 204 may impart impact resistance functionality. The polymeric component of the polymeric encapsulating matrix 116 may include UV-curable polymers, including but not limited to silicone polymers, acrylic polymers, or combinations thereof. The polymeric component of the polymeric encapsulating matrix 116 may also be cross-linked.

As illustrated in FIGS. 1-3, the shear-thinning fluid or the shear-thickening fluid may be dispersed within the impact-load distributing layer 102 or the second impact-load-distributing layer 112, respectively, which is within the gasket 114. The gasket 114 may include rubber materials, cross-linked polymer composites, resins, adhesive films, or combinations thereof. It is contemplated that a wide variety of materials may be suitable for the gasket 114.

As described herein, the laminated glass articles may include one or more components/layers. In embodiments, each of these components/layers, such as the first polymer layer, the impact-load-distributing layer, the glass layer, the adhesive layer, the second polymer layer, the second impact-load-distributing layer, may be optically transparent. As used herein, an “optically transparent” material means an average transmittance of 70% or more in the wavelength range of 400 nm to 700 nm through a 1.0 mm thick piece of a that material. In embodiments, an optically transparent material may have an average transmittance of 75% or more, 80% or more, 85% or more, or 90% or more in the wavelength range of 400 nm to 700 nm through a 1.0 mm thick piece of the material. The average transmittance in the wavelength range of 400 nm to 700 nm is calculated by measuring the transmittance of all whole number wavelengths from 400 nm to 700 nm and averaging the measurements. In some embodiments, the laminated glass article is optically transparent, where such optical transparency is measured by having an average transmittance of 70% or more through the thickness of the laminated glass article.

Also as described herein, the laminated glass articles, as well as the individual components/layers within, such as the first polymer layer, the impact-load-distributing layer, the glass layer, the adhesive layer, the second polymer layer, the second impact-load-distributing layer, or combinations thereof, may be flexible. As previously described, “flexible” refers to a layer or article having a bend radius, by itself, of less than or equal to 10 millimeters (mm). For example, and in embodiments, the laminated glass articles, or any individual layer therein, previously described may have a bend radius of 10 mm or less, such as from 1 mm to 10, from 1 mm to 5 mm, from 5 mm to 10 mm, or any smaller range therein, such as from 3 mm to 4 mm.

In one or more embodiments, the laminated glass articles 100 mentioned herein may be incorporated into another article, for example, an article with a display (or display articles) (e.g., consumer electronic products, including mobile phones, tablets, computers, navigation systems, wearable devices (e.g., watches) and the like), architectural articles, transportation articles (e.g., automotive, trains, aircraft, sea craft, etc.), appliance articles, or any article that may benefit from some transparency or impact resistance.

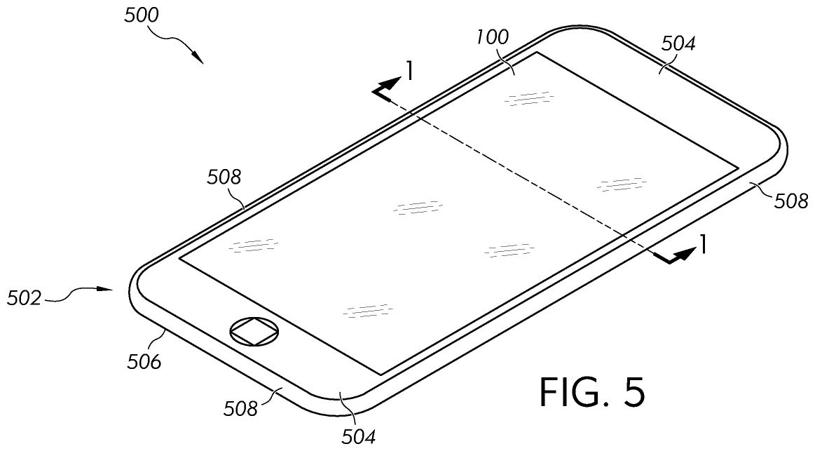

Now referring to FIG. 5, an exemplary article incorporating any of the glass laminated articles 100 discussed herein may be a consumer electronic device 500 including a housing 502 having front surface 504, back surface 506, and side surfaces 508; electrical components (not shown in FIG. 5) that are at least partially inside or entirely within the housing 502 and including at least a controller, a memory, and a display (such as an electronic display) at or adjacent to the front surface of the housing 502; and wherein one or both of the front surface 504 and the back surface 506 include any of the laminated glass articles 100 discussed herein.

Another exemplary article incorporating any of the glass laminated articles 100 herein may be an electronic display component including an electronic display. The electronic display may include a display surface. In such embodiments, all or a portion of the laminated glass article 100, such as a top surface of the laminated glass article 100, may be the display surface of the electronic display or electronic display component. In other words, the display surface may define all or a portion of the top surface of the laminated glass article 100. In this manner, the first polymer layer 106 or the impact-load distributing layer 102 of the laminated glass article 100 may be disposed over or disposed on the electronic display. Exemplary electronic displays include a light emitting diode (LED) display or an organic light emitting diode (OLED) display.

Another exemplary article incorporating any of the glass laminated articles herein may be a non-electronic display component including a non-electronic display. For example, the non-electric display may be a display device that displays static or printed indicia. In embodiments, the non-electric display may be or may include a touch sensor, such as a capacitive touch sensor, a polarizer, or a battery. Similar to or identical to the electronic display component, the non-electronic display may also include a display surface. In such embodiments, all or a portion of the laminated glass article 100, such as a top surface of the laminated glass article 100, may be the display surface of the non-electronic display or electronic display component. In other words, the display surface may define all or a portion of the top surface of the laminated glass article 100. In this manner, the first polymer layer 106 or the impact-load distributing layer 102 of the laminated glass article 100 may be disposed over or disposed on the non-electronic display.

### EXAMPLES

Examples are provided herein which may disclose one or more embodiments of the present disclosure. However, the Examples should not be viewed as limiting on the claimed embodiments hereinafter provided.

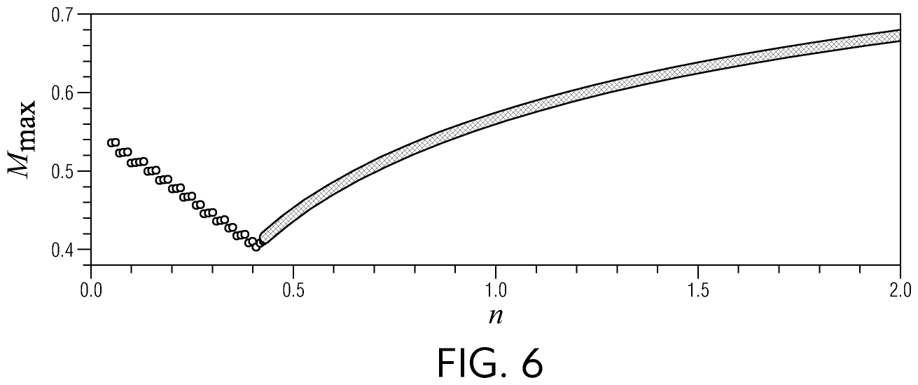

Mathematical modeling was conducted to show the predicted response to impact for a non-Newtonian power-law fluid based laminate. FIG. 6 shows modeled response for peak bending moment for decelerating impact with changing power-law index, Mₘₐₓ(n), for optimal impact parameter, i.e., varying consistency K, to minimum. The FIG. 6 data was calculated based on a rigid base layer, a flexible glass sheet above the rigid base layer (impact side), with a non-Newtonian fluid between the two. As is shown, minimized peak bending moments of as low as about 0.4 can be modeled when the n (flow behavior index) is at about 0.4, with a trough in peak bending moment at n equals about 0.4.

The present disclosure includes several aspects. One aspect is a laminated glass article comprising: a first polymer layer; an impact-load-distributing layer comprising a shear-thinning fluid, the impact-load-distributing layer disposed over the first polymer layer; a glass layer disposed on the impact-load-distributing layer; an adhesive layer disposed over the glass layer; and a second polymer layer disposed over the adhesive layer; wherein the laminated glass article has a bend radius of 10 millimeters or less.

Another aspect is any one above aspect or combination of above aspects, wherein the shear-thinning fluid has a flow behavior index of less than 1.0.

Another aspect is any one above aspect or combination of above aspects, wherein the shear-thinning fluid has a flow behavior index of less than 0.9.

Another aspect is any one above aspect or combination of above aspects, wherein the shear-thinning fluid has a flow behavior index of from 0.2 to 0.6.

Another aspect is any one above aspect or combination of above aspects, wherein the shear-thinning fluid has a flow behavior index of from 0.3 to 0.5.

Another aspect is any one above aspect or combination of above aspects, wherein the impact-load-distributing layer has a thickness in a range of 1 micron to 100 microns.

Another aspect is any one above aspect or combination of above aspects, wherein the shear-thinning fluid comprises a suspension of polyethylene glycol and hydrophobic fumed silica.

Another aspect is any one above aspect or combination of above aspects, wherein the shear-thinning fluid comprises from 1 wt. % to 7 wt. % hydrophobic fumed silica, measured by the weight of the shear-thinning fluid.

Another aspect is any one above aspect or combination of above aspects, wherein the hydrophobic fumed silica has an average particle size of less than 1 micron or less than 200 nanometers.

Another aspect is any one above aspect or combination of above aspects, wherein the impact-load-distributing layer further comprises an encapsulating material surrounding the shear-thinning fluid, the encapsulating material in direct contact with and interposed between the first polymer layer and the glass layer.

Another aspect is any one above aspect or combination of above aspects, wherein the encapsulating material comprises a gasket, a polymeric encapsulating matrix, or both.

Another aspect is any one above aspect or combination of above aspects, wherein the glass layer comprises a thickness in a range of 1 micron to 200 microns.

Another aspect is any one above aspect or combination of above aspects, wherein the glass layer has a bend radius of 10 millimeters or less.

Another aspect is any one above aspect or combination of above aspects, wherein the adhesive layer comprises a viscoelastic material, a shear thickening material, or combinations thereof.

Another aspect is any one above aspect or combination of above aspects, wherein the adhesive layer comprises a polyacrylic.

Another aspect is any one above aspect or combination of above aspects, wherein the second polymer layer comprises polyethylene terephthalates, polyimides, polycarbonates, or combinations thereof.

Another aspect is any one above aspect or combination of above aspects, wherein the first polymer layer comprises polyethylene terephthalates, polyimides, polycarbonates, or combinations thereof.

Another aspect is any one above aspect or combination of above aspects, further comprising a second impact-load-distributing layer comprising a shear-thickening fluid disposed on the glass layer.

Another aspect is any one above aspect or combination of above aspects, wherein the shear-thickening fluid comprises a suspension of polyethylene glycol and hydrophilic fumed silica.

Another aspect is any one above aspect or combination of above aspects, wherein the shear-thickening fluid comprises from 1 wt. % to 20 wt. % hydrophilic fumed silica measured by the weight of the shear-thickening fluid.

Another aspect is any one above aspect or combination of above aspects, further comprising an electronic display positioned under the first polymer layer.

Another aspect is any one above aspect or combination of above aspects, wherein: the impact-load-distributing layer is in direct contact with the first polymer layer; the adhesive layer is in direct contact with the glass layer; and the second polymer film is in direct contact with the adhesive layer.

Another aspect is an electronic device comprising: a housing comprising a front surface, a back surface, and side surfaces; electrical components at least partially within the housing, the electrical components comprising a controller, a memory, and an electronic display, the electronic display at or adjacent the front surface of the housing; and wherein one or both of the front surface and the back surface comprise the laminated glass article of any other aspect, wherein the second polymer layer is outward facing as compared to the first polymer layer.

Another aspect is a laminated glass article comprising: an impact-load-distributing layer comprising a shear-thinning fluid; and a glass layer disposed on the impact-load-distributing layer; wherein the laminated glass article has a bend radius of 10 millimeters or less.

Directional terms as used herein—for example up, down, right, left, front, back, top, bottom—are made with reference to the figures as drawn and are not intended to imply absolute orientation.

The subject matter of the present disclosure has been described in detail and by reference to specific embodiments. It should be understood that any detailed description of a component or feature of an embodiment does not necessarily imply that the component or feature is essential to the particular embodiment or to any other embodiment. Further, it should be apparent to those skilled in the art that various modifications and variations can be made to the described embodiments without departing from the spirit and scope of the claimed subject matter.

It is noted that one or more of the following claims utilize the term “wherein” as a transitional phrase. For the purposes of defining the present technology, it is noted that this term is introduced in the claims as an open-ended transitional phrase that is used to introduce a recitation of a series of characteristics of the structure and should be interpreted in like manner as the more commonly used open-ended preamble term “comprising.”

It should be understood that where a first component is described as “comprising” a second component, it is contemplated that, in embodiments, the first component “consists” or “consists essentially of” that second component. It should further be understood that where a first component is described as “comprising” a second component, it is contemplated that, in embodiments, the first component comprises at least 10%, at least 20%, at least 30%, at least 40%, at least 50%, at least 60%, at least 70%, at least 80%, at least 90%, at least 95%, or even at least 99% that second component (where % can be weight % or molar %).

For the purposes of describing and defining the present inventive technology, it is noted that reference herein to a variable being a “function” of a parameter or another variable is not intended to denote that the variable is exclusively a function of the listed parameter or variable. Rather, reference herein to a variable that is a “function” of a listed parameter is intended to be open ended such that the variable may be a function of a single parameter or a plurality of parameters.

It is also noted that recitations herein of “at least one” component, element, etc., should not be used to create an inference that the alternative use of the articles “a” or “an” should be limited to a single component, element, etc.

Where a range of numerical values is recited herein, comprising upper and lower values, unless otherwise stated in specific circumstances, the range is intended to include the endpoints thereof, and all integers and fractions within the range. It is not intended that the scope of the claims be limited to the specific values recited when defining a range. It should also be understood that any two quantitative values assigned to a property may constitute a range of that property, and all combinations of ranges formed from all stated quantitative values of a given property are contemplated herein.

1. A laminated glass article comprising:
a first polymer layer;
an impact-load-distributing layer comprising a shear-thinning fluid, the impact-load-distributing layer disposed over the first polymer layer;
a glass layer disposed on the impact-load-distributing layer;
an adhesive layer disposed over the glass layer; and
a second polymer layer disposed over the adhesive layer;
wherein the laminated glass article has a bend radius of 10 millimeters or less.

2. The laminated glass article of claim 1, wherein the shear-thinning fluid has a flow behavior index of less than 1.0.

3. The laminated glass article of claim 1, wherein the shear-thinning fluid has a flow behavior index of less than 0.9.

4. (canceled)

5. (canceled)

6. The laminated glass article of claim 1, wherein the impact-load-distributing layer has a thickness in a range of 1 micron to 100 microns.

7. The laminated glass article of claim 1, wherein the shear-thinning fluid comprises a suspension of polyethylene glycol and hydrophobic fumed silica.

8. The laminated glass article of claim 7, wherein the shear-thinning fluid comprises from 1 wt. % to 7 wt. % hydrophobic fumed silica, measured by the weight of the shear-thinning fluid.

9. The laminated glass article of claim 7, wherein the hydrophobic fumed silica has an average particle size of less than 1 micron or less than 200 nanometers.

10. The laminated glass article of claim 1, wherein the impact-load-distributing layer further comprises an encapsulating material surrounding the shear-thinning fluid, the encapsulating material in direct contact with and interposed between the first polymer layer and the glass layer.

11. The laminated glass article of claim 10, wherein the encapsulating material comprises a gasket, a polymeric encapsulating matrix, or both.

12. The laminated glass article of claim 1, wherein the glass layer comprises a thickness in a range of 1 micron to 200 microns.

13. (canceled)

14. The laminated glass article of claim 1, wherein the adhesive layer comprises a viscoelastic material, a shear thickening material, or combinations thereof.

15. The laminated glass article of claim 1, wherein the adhesive layer comprises a polyacrylic.

16. The laminated glass article of claim 1, wherein the second polymer layer comprises polyethylene terephthalates, polyimides, polycarbonates, or combinations thereof.

17. The laminated glass article of claim 1, wherein the first polymer layer comprises polyethylene terephthalates, polyimides, polycarbonates, or combinations thereof.

18. The laminated glass article of claim 1, further comprising a second impact-load-distributing layer comprising a shear-thickening fluid disposed on the glass layer.

19. (canceled)

20. (canceled)

21. The laminated glass article of claim 1, further comprising an electronic display positioned under the first polymer layer.

22. The laminated glass article of claim 1, wherein:
the impact-load-distributing layer is in direct contact with the first polymer layer;
the adhesive layer is in direct contact with the glass layer; and
the second polymer film is in direct contact with the adhesive layer.

23. An electronic device comprising:
a housing comprising a front surface, a back surface, and side surfaces;
electrical components at least partially within the housing, the electrical components comprising a controller, a memory, and an electronic display, the electronic display at or adjacent the front surface of the housing; and
wherein one or both of the front surface and the back surface comprise the laminated glass article of claim 1, wherein the second polymer layer is outward facing as compared to the first polymer layer.

24. A laminated glass article comprising:
an impact-load-distributing layer comprising a shear-thinning fluid; and
a glass layer disposed on the impact-load-distributing layer;
wherein the laminated glass article has a bend radius of 10 millimeters or less.

25. An electronic device comprising:
a housing comprising a front surface, a back surface, and side surfaces;
electrical components at least partially within the housing, the electrical components comprising a controller, a memory, and an electronic display, the electronic display at or adjacent the front surface of the housing; and
wherein one or both of the front surface and the back surface comprise the laminated glass article of claim 1, wherein the glass layer is outward facing as compared to the substrate.
